(19) United States
(12) Patent Application Publication
(10) Pub. No.: US 2024/0395653 A1
(43) Pub. Date: Nov. 28, 2024

(54) HEAT DISSIPATION MEMBER, METHOD OF MANUFACTURING THE HEAT DISSIPATION MEMBER, AND SEMICONDUCTOR DEVICE INCLUDING THE HEAT DISSIPATION MEMBER

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP)

(72) Inventors: MASAKI AOSHIMA, Nisshin-shi (JP); TOMOHITO IWASHIGE, Nisshin-shi (JP)

(21) Appl. No.: 18/665,769

(22) Filed: May 16, 2024

(30) Foreign Application Priority Data
May 23, 2023 (JP) 2023-084705

(51) Int. Cl. H01L 23/367; H01L 21/48; H01L 23/373

(52) U.S. Cl. CPC H01L 23/367; H01L 21/4878; H01L 21/4882; H01L 23/3737

(57) ABSTRACT

A heat dissipation member is provided between a first member and a second member in a first direction and compressed by the first and second member to conduct heat between the first and second member. The heat dissipation member includes thermally conductive members each having one end portion provided at one end in the first direction and thermally connected to the first member and an other end portion provided at an other end in the first direction. The thermally conductive members are thermally connected to the second member. The thermally conductive members are arranged side by side in a second direction perpendicular to the first direction and conduct heat between the one end portion and the other end portion. Each of the thermally conductive members has a curved shape which is bent or curved in a cross section taken along the first direction and the second direction.

### CROSS REFERENCE TO RELATED APPLICATION

This application is based on and claims the benefits of priority of Japanese Patent Application No. 2023-084705 filed on May 23, 2023. The entire disclosure of which is incorporated herein by reference.

### TECHNICAL FIELD

The present invention relates to a heat dissipation member that conducts heat between members, a method of manufacturing the heat dissipation member, and a semiconductor device including the heat dissipation member.

### BACKGROUND

A conventional heat dissipation sheet includes base material layers and diamond layers.

### SUMMARY

According to at least one embodiment, a heat dissipation member is provided between a first member and a second member in a first direction and compressed by the first and second member to conduct heat between the first and second member. The heat dissipation member includes thermally conductive members each having one end portion provided at one end in the first direction and thermally connected to the first member and an other end portion provided at an other end in the first direction. The thermally conductive members are thermally connected to the second member. The thermally conductive members are arranged side by side in a second direction perpendicular to the first direction and conduct heat between the one end portion and the other end portion. Each of the thermally conductive members has a curved shape which is bent or curved in a cross section taken along the first direction and the second direction.

### BRIEF DESCRIPTION OF DRAWINGS

The details of one or more embodiments are set forth in the accompanying drawings and the description below. Other features and advantages will be apparent from the description and drawings, and from the claims.

FIG. 1 is a cross-sectional view illustrating a schematic configuration of a semiconductor device according to a first embodiment.

FIG. 2 is a cross-sectional view taken along a line II-II of FIG. 1.

FIG. 3 is an enlarged view of a heat dissipation member in a portion III of FIG. 1, and is a cross-sectional view schematically illustrating the heat dissipation member in a no-load state in which a compressive force for compressing the heat dissipation member does not act.

FIG. 4 is a diagram illustrating a high thermal conduction direction Dh and a low thermal conduction direction of graphene constituting thermally conductive member of the heat dissipation member in the first embodiment.

FIG. 5 is a cross-sectional view illustrating a schematic configuration of a semiconductor device of a comparative example, and corresponds to FIG. 1.

FIG. 6 is an enlarged view of the heat dissipation member in which a portion VI in FIG. 5 is enlarged in a comparative example.

FIG. 7 is a cross-sectional view corresponding to FIG. 6 in a comparative example, showing a heat dissipation member in a no-load state.

FIG. 8 is a flowchart illustrating a manufacturing process of the heat dissipation member of the first embodiment and the comparative example.

FIG. 9A is a perspective view illustrating a thermally conductive sheet wound around a core material in step S02 of FIG. 8 in the first embodiment and the comparative example.

FIG. 9B is a perspective view illustrating a roll member obtained by winding the thermally conductive sheet around the core material multiple times in step S02 of FIG. 8 in the comparative example.

FIG. 9C is a perspective view illustrating one of divided roll members obtained by dividing the roll member in an axial direction in step S03 of FIG. 8 in the comparative example.

FIG. 9D is an arrow view taken along a direction of IXd in FIGS. 9B, 9C in the comparative example.

FIG. 10 is a perspective view illustrating the roll member obtained by winding the thermally conductive sheet around the core material multiple times in step S02 of FIG. 8 in the first embodiment, and is a view corresponding to FIG. 9B.

FIG. 11 is a view taken along a direction of arrow XI in FIG. 10 and corresponding to FIG. 9D in the first embodiment.

FIG. 12 is a diagram illustrating measurement results obtained by measuring thermal resistance characteristics at a time of compression, which is a relationship between module thermal resistance and a compressive load on the heat dissipation member, in each of the present embodiment and the comparative example.

FIG. 13 is an enlarged cross-sectional view illustrating a part of a heat dissipation member in the no-load state in a second embodiment, and is a view corresponding to FIG. 3.

FIG. 14 is an enlarged cross-sectional view illustrating a part of a heat dissipation member in the no-load state in a third embodiment, and is a view corresponding to FIG. 3.

FIG. 15 is a diagram illustrating a cutting operation of cutting out the heat dissipation member with a cutting tool in the manufacturing process of the heat dissipation member according to the third embodiment.

FIG. 16 is a partially enlarged view illustrating a portion XVI of FIG. 15 in the third embodiment.

FIG. 17 is a flowchart illustrating a manufacturing process of the heat dissipation member of a sixth embodiment, and is a diagram corresponding to FIG. 8.

FIG. 18 is a cross-sectional view illustrating a part of a developed material obtained by developing a divided roll member in the sixth embodiment.

### DETAILED DESCRIPTION

To begin with, examples of relevant techniques will be described.

A heat dissipation sheet of a comparative example includes base material layers and diamond layers. In the heat dissipation sheet of the comparative example, the base material layer and the diamond layer, which is a thermally conductive member having high thermal conductivity, are alternately laminated in a stacking direction perpendicular to a thickness direction of the heat dissipation sheet. Each of the diamond layers linearly extends from one end to the other end in the thickness direction in a cross section along the thickness direction of the heat dissipation sheet and the stacking direction.

A heat dissipation member such as the heat dissipation sheet of the comparative example is sandwiched between a first member disposed on one side in the thickness direction of the heat dissipation member and a second member disposed on the other side in the thickness direction, and is held in a state of being compressed by the first member and the second member. As a result, the heat dissipation member conducts heat between the first member and the second member.

Here, it is assumed that thermally conductive members arranged in the stacking direction in the heat dissipation member have the same shape as the diamond layer included in the heat dissipation sheet of the comparative example. That is, it is assumed that the thermally conductive members have a shape linearly extending from one end to the other side in the thickness direction of the heat dissipation member in a cross section along the thickness direction of the heat dissipation member and the stacking direction.

In a case where the thermally conductive member has such a linearly extending shape, when a compressive force that compresses the heat dissipation member in the thickness direction is applied to the heat dissipation member, each of the thermally conductive members is inclined so as to fall with respect to the thickness direction of the heat dissipation member. As the compressive force increases, the inclination angle of the thermally conductive member with respect to the thickness direction increases.

In addition, the inventors have confirmed that when the compressive force applied to the heat dissipation member is equal to or greater than a certain magnitude, thermal resistance between the first member and the second member sandwiching the heat dissipation member significantly increases. This is because, due to the inclination of each of the thermally conductive members, a contact area between an end portion of the thermally conductive member and a contact counterpart member which is the first member or the second member facing the end portion is reduced, or the end portion is separated from the contact counterpart member. The above has been found as a result of detailed studies by the inventors.

In view of the above, an object of the present invention is to avoid a phenomenon in which thermal resistance between a first member and a second member sandwiching a heat dissipation member increases with an increase in compressive force applied to the heat dissipation member.

According to an aspect of the present disclosure, a heat dissipation member is provided between a first member and a second member in a first direction and compressed by the first and second member to conduct heat between the first and second member. The heat dissipation member includes thermally conductive members each having one end portion provided at one end in the first direction and thermally connected to the first member and an other end portion provided at an other end in the first direction. The thermally conductive members are thermally connected to the second member. The thermally conductive members are arranged side by side in a second direction perpendicular to the first direction and conduct heat between the one end portion and the other end portion. Each of the thermally conductive members has a curved shape which is bent or curved in a cross section taken along the first direction and the second direction.

With this configuration, as compressive force for compressing the heat dissipation member in the first direction increases, degree of bending or curving in the curved shape of the thermally conductive members increases, and thus the thermally conductive members generate a reaction force against the compressive force. Since the thermally conductive members have the curved shape, even when the compressive force applied to the heat dissipation member increases, the actions of the one end portion of the thermally conductive member being displaced in the second direction with respect to the other end portion is unlikely to occur. Therefore, the one end portion of the thermally conductive member is less likely to slip on a surface of the first member with which the one end portion is in contact, and the other end portion of the thermally conductive member is less likely to slip on a surface of the second member with which the other end portion is in contact.

For this reason, for example, as compared with a case where the thermally conductive member does not have a curved shape but has a linear cross-sectional shape, even when the compressive force applied to the heat dissipation member increases, the contact area between the one end portion of the thermally conductive member and the first member and the contact area between the other end portion of the thermally conductive member and the second member are less likely to decrease. Therefore, a phenomenon in which the thermal resistance between the first member and the second member sandwiching the heat dissipation member increases with an increase in the compressive force applied to the heat dissipation member.

Hereinafter, embodiments are described with reference to the drawings. In the following embodiments, the same or equivalent parts are denoted by the same reference numerals in the drawings.

### First Embodiment

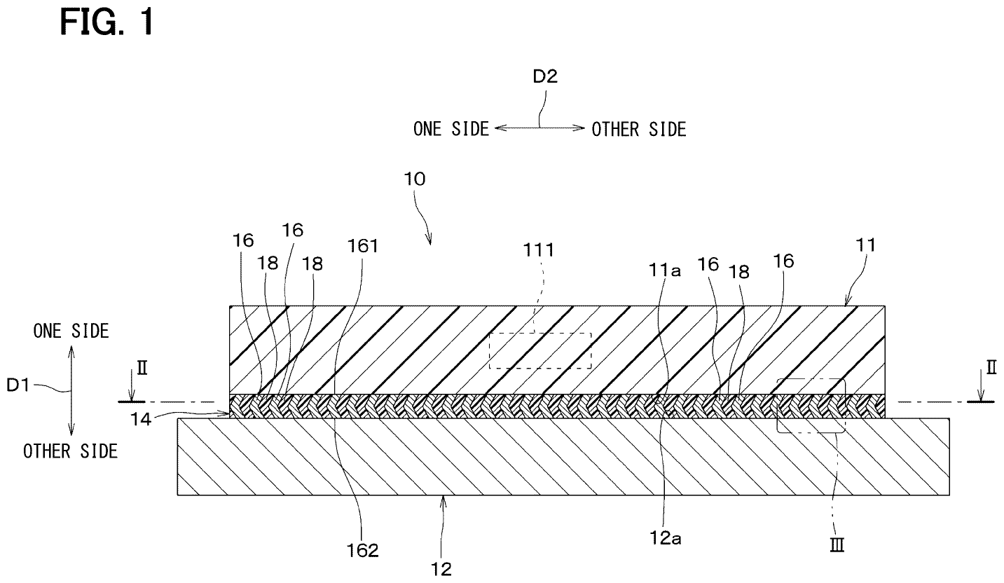

As shown in FIG. 1, a semiconductor device 10 of the present embodiment includes a first member 11, a second member 12, and a heat dissipation member 14. The first member 11, the heat dissipation member 14, and the second member 12 are stacked in the order of the first member 11, the heat dissipation member 14, and the second member 12 from one side in a first direction D1. That is, the heat dissipation member 14 is sandwiched between the first member 11 and the second member 12. Note that the drawings used in the description of the present embodiment and embodiments described later are appropriately deformed in order to show the components of the semiconductor device 10 in an easy-to-understand manner.

The first member 11 is a semiconductor component including the semiconductor element 111. For example, an outer shell of the first member 11 is formed of a resin covering the semiconductor element 111. The first member 11 generates heat when the semiconductor element 111 is energized. For example, the first member 11 has a flat shape having a thickness in the first direction D1. The first member 11 has a contact surface 11a provided on the other side of the first member 11 opposite to the one side in the first direction D1, and the contact surface 11a is in contact with the heat dissipation member 14.

The second member 12 is, for example, a member constituting a part of a cooler for cooling the first member 11. The cooler may dissipate heat by a structure having heat dissipation fins, or may dissipate heat via a coolant circulating inside the cooler.

The second member 12 is made of a metal having high thermal conductivity such as an aluminum alloy. The second member 12 has a contact surface 12a provided on one side of the second member 12 in the first direction D1, and the contact surface 12a is in contact with the heat dissipation member 14.

The heat dissipation member 14 is a flexible sheet-like object, and is provided with the first direction D1 as a thickness direction of the heat dissipation member 14. The heat dissipation member 14 has elasticity capable of being elastically compressed in the first direction D1.

The heat dissipation member 14 is disposed between the first member 11 and the second member 12, and is held in a compressed state in which the heat dissipation member 14 is elastically compressed in the first direction D1 by the first member 11 and the second member 12. The heat dissipation member 14 thus held in the compressed state conducts heat well between the first member 11 and the second member 12. For example, the compressed state of the heat dissipation member 14 is held by a clamp mechanism (not shown) or the like. In the drawings described later, the heat dissipation member 14 may be displayed in a no-load state in which the heat dissipation member 14 is not compressed. However, in FIG. 1, the heat dissipation member 14 is displayed in the compressed state.

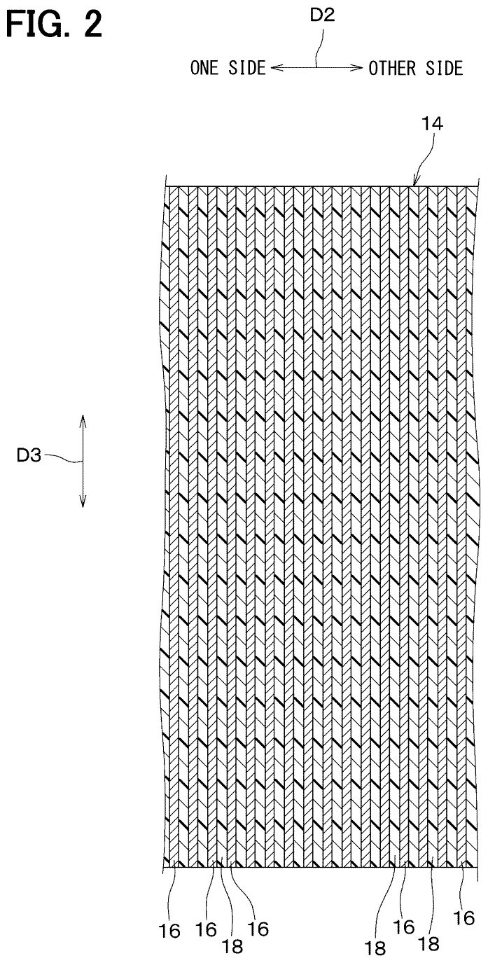

As shown in FIGS. 1, 2, the heat dissipation member 14 includes thermally conductive members 16 and bonding materials 18. The thermally conductive member 16 and the bonding materials 18 are each formed in a layer shape, and are stacked so as to be alternately arranged in a second direction D2 perpendicular to the first direction D1. Each of the thermally conductive members 16 extends in a third direction D3 perpendicular to the first direction D1 and the second direction D2, and each of the bonding materials 18 also extends in the third direction D3.

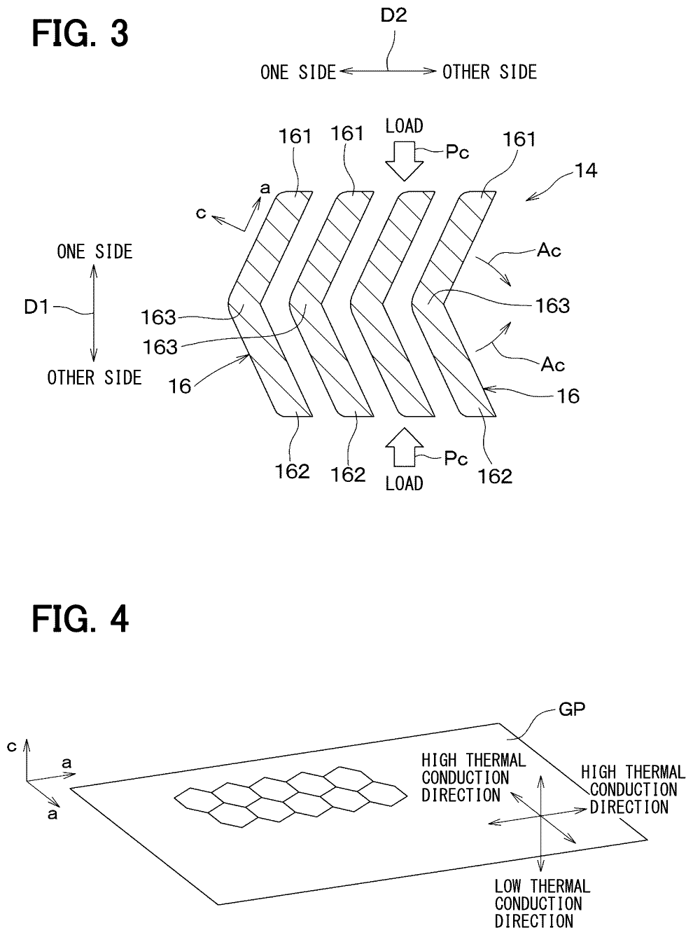

Each of the thermally conductive members 16 is provided to provide the heat dissipation member 14 with high thermal conductivity, and has higher thermal conductivity than the bonding material 18. As shown in FIGS. 1, 3, each of the thermally conductive members 16 has one end portion 161 provided on one end in the first direction D1 and the other end portion 162 provided on the other end in the first direction D1.

FIG. 3 is an enlarged view of a portion III in FIG. 1. In FIG. 3, only the thermally conductive member 16 of the heat dissipation member 14 is extracted and displayed. This display method is also applied to a diagram corresponding to FIG. 3, which will be described later.

Each of the thermally conductive members 16 is connected to the first member 11 at one end portion 161 in a thermally conductive manner, and is connected to the second member 12 at the other end portion 162 in the thermally conductive manner. More specifically, one end portion 161 of the thermally conductive member 16 is in contact with the contact surface 11a of the first member 11, and the other end portion 162 of the thermally conductive member 16 is in contact with the contact surface 12a of the second member 12. Each of the thermally conductive members 16 conducts heat between the one end portion 161 and the other end portion 162.

As shown in FIGS. 1, 3, each of the thermally conductive members 16 has a bent shape which is bent or curved in a first cross section which is a cross section taken in both the first direction D1 and the second direction D2. For example, in the first cross section in FIG. 3, the curved shape of the thermally conductive member 16 is a shape in which one side in the second direction D2 is convex and the other side in the second direction D2 is concave as a whole. The thermally conductive member 16 is bent into an L-shape.

More specifically, each of the thermally conductive members 16 has a bent portion 163 at an intermediate position away from both the one end portion 161 and the other end portion 162 within a range between the one end portion 161 and the other end portion 162 in the first direction D1. The bent portion 163 has a shape bent to be convex toward one side in the second direction D2. That is, the curved shape of the thermally conductive member 16 is a shape bent so as to be convex toward one side in the second direction D2 at the intermediate position in the first direction D1.

The shape of the thermally conductive member 16 shown in FIG. 3 is a shape in the no-load state in which the heat dissipation member 14 is not compressed. For the sake of confirmation, the thermally conductive member 16 still has the above-described bent shape even in a no-load state of the heat dissipation member 14 or in the compressed state in which the compressive load Pc acts on the heat dissipation member 14 and the heat dissipation member 14 is elastically compressed. This is because, in the compressed state of the heat dissipation member 14, the thermally conductive member 16 is bent as indicated by an arrow Ac in FIG. 3 as compared with the no-load state, and a degree of bending at the bent portion 163 is only increased.

Regarding the constituent material of the thermally conductive member 16, the thermally conductive member 16 is made of a material whose thermal conductivity in thermal conduction between the one end portion 161 and the other end portion 162 is higher than the thermal conductivity of tin (that is, Sn). More specifically, the thermally conductive member 16 of the present embodiment is made of a carbon material composed of carbon atoms, that is, graphite. More specifically, the thermally conductive member 16 has sheet-shaped graphenes GP, and the graphenes GP are stacked in the thickness direction of the thermally conductive member 16 in the cross section of the thermally conductive member in FIG. 3. The thickness direction of the thermally conductive member 16 is, for example, the second direction D2 or substantially the second direction D2 in FIG. 3.

Here, as shown in FIG. 4, the thermal conductivity of the graphene GP has anisotropy, and the graphene GP has a high thermal conduction direction Dha and a low thermal conduction direction Dlc in which the thermal conductivity is small with respect to the high thermal conduction direction Dha. The high thermal conduction direction Dha is a direction along the sheet shape of the graphene GP, that is, a surface direction of the graphene GP, and the low thermal conduction direction Dlc is a direction perpendicular to the sheet shape of the graphene GP, that is, a normal direction of the graphene GP.

As shown in FIGS. 3, 4, the graphenes GP constituting the thermally conductive member 16 are disposed such that the high thermal conduction direction Dha of the graphenes GP is along a heat conduction path connecting the one end portion 161 and the other end portion 162 of the thermally conductive member 16 along the curved shape of the thermally conductive member 16.

As shown in FIGS. 1, 2, each of the bonding materials 18 is a binder resin that bonds the thermally conductive members 16 arranged in the second direction D2 to each other, and is filled between the thermally conductive members 16. For example, the bonding material 18 is solidified to bond the adjacent thermally conductive members 16 to each other.

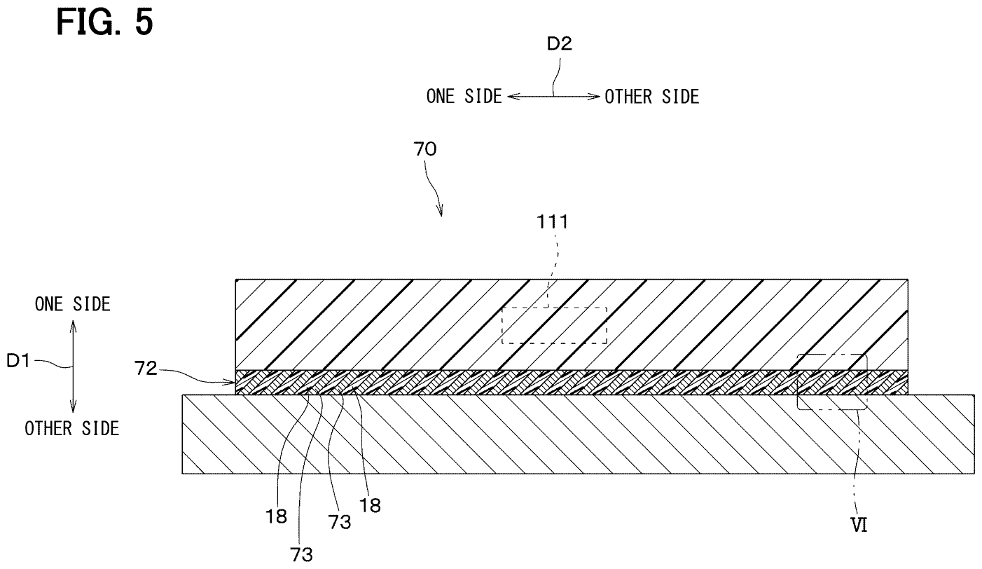

Here, a semiconductor device 70 of a comparative example will be described as a comparison to the present embodiment. As shown in FIG. 5, the semiconductor device 70 of the comparative example is different from the semiconductor device 10 of the present embodiment in that the heat dissipation member 14 of the present embodiment is replaced with a heat dissipation member 72 corresponding to the heat dissipation member 14 of the present embodiment. The semiconductor device 70 of the comparative example is different from the semiconductor device 10 of the present embodiment in the shape of thermally conductive members 73 constituting the heat dissipation member 72 of the semiconductor device 70.

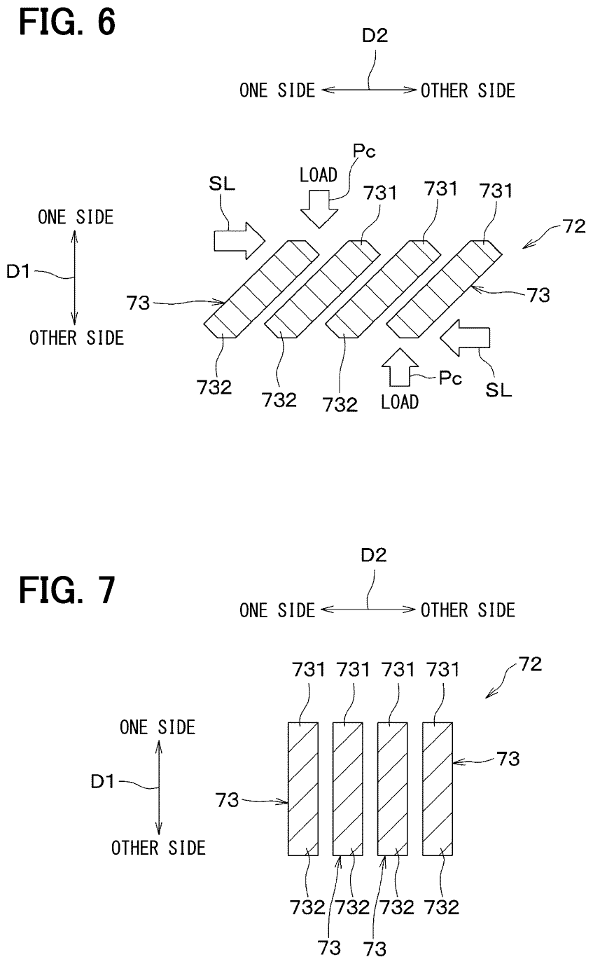

More specifically, as shown in FIGS. 6, 7, each of the thermally conductive members 73 of the comparative example has one end 731 corresponding to the one end portion 161 of the present embodiment and the other end 732 corresponding to the other end portion 162 of the present embodiment. FIG. 6 shows the shape of the heat dissipation member 72 in the compressed state, and FIG. 7 shows the shape of the heat dissipation member 72 in a no-load state. FIG. 6 corresponds to FIG. 3, and is a cross-sectional view illustrating the heat dissipation member 72 in the compressed state in which the heat dissipation member 72 is elastically compressed in the first direction D1. Each of the thermally conductive members 73 of the comparative example does not have a curved shape in the first cross section, but has a shape linearly extending between the one end 731 and the other end 732.

The semiconductor device 70 of the comparative example is different from the semiconductor device 10 of the present embodiment as described above, and the semiconductor device 70 of the comparative example is the same as the semiconductor device 10 of the present embodiment in the other points.

Next, a method of manufacturing each of the heat dissipation member 14 of the present embodiment and the heat dissipation member 72 of the comparative example will be described. Since the method of manufacturing the heat dissipation member 14 of the present embodiment is a modification of the method of manufacturing the heat dissipation member 72 of the comparative example, the method of manufacturing the heat dissipation member 72 of the comparative example will be described first.

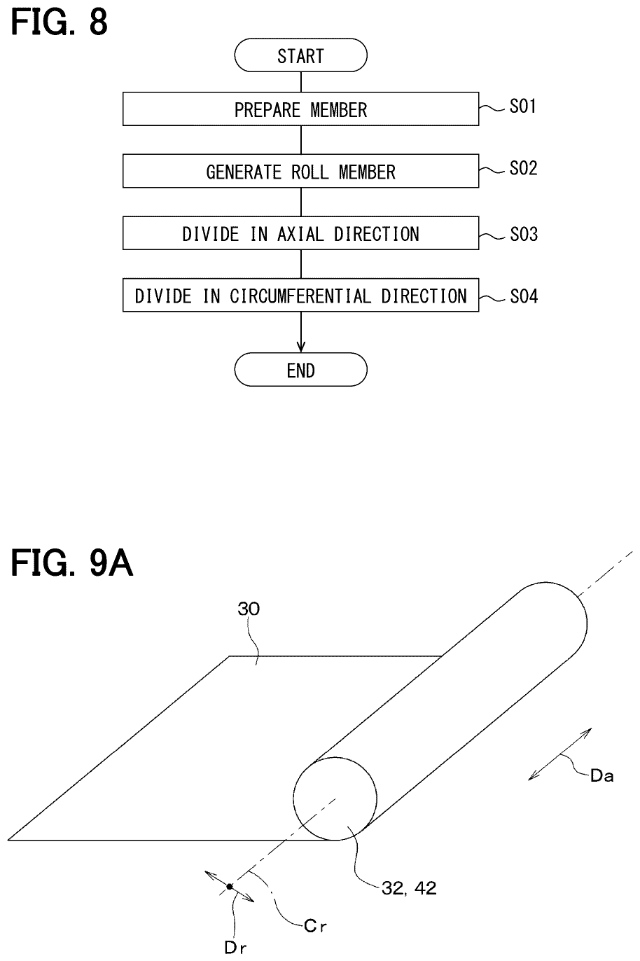

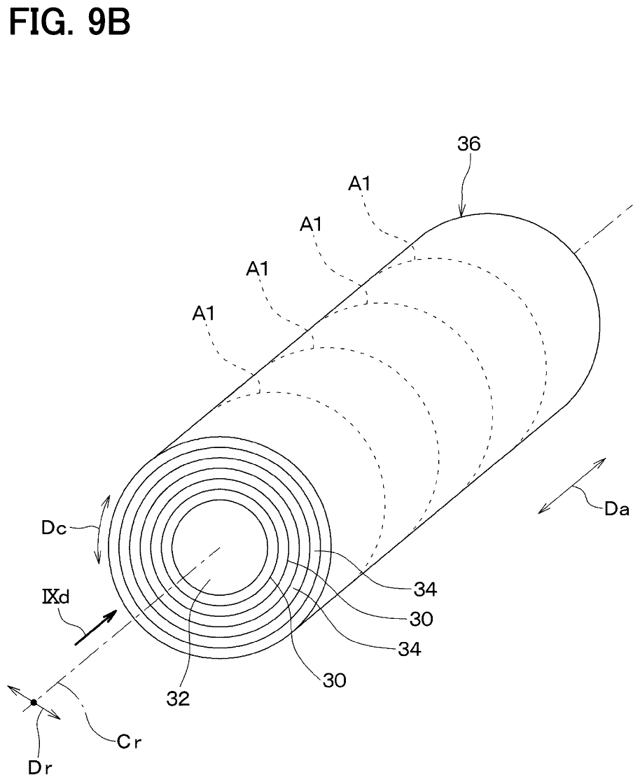

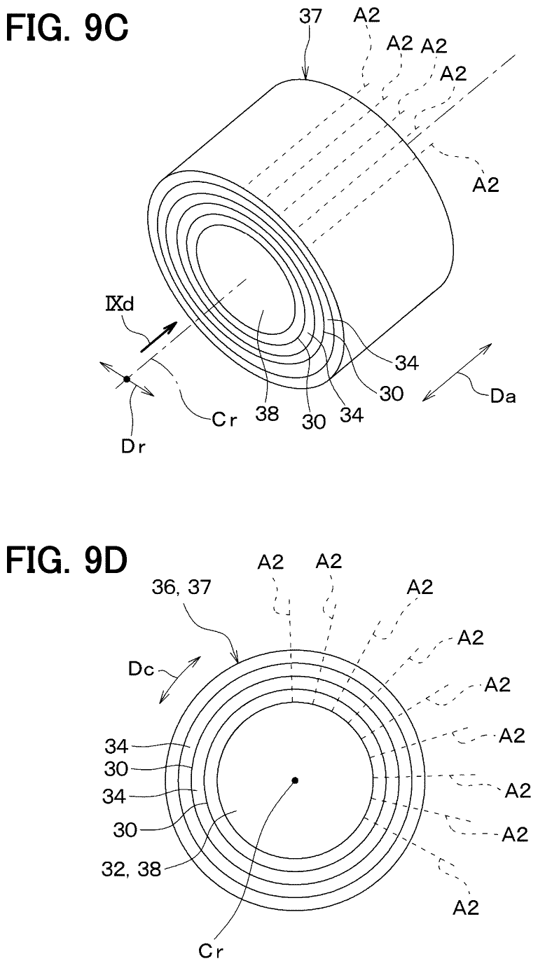

In the manufacturing of the heat dissipation member 72 of the comparative example, in step S01 of FIG. 8, first, as shown in FIG. 9A, a sheet-like thermally conductive sheet 30 having heat conductivity is prepared. The thermally conductive sheet 30 is a member serving as a base of the thermally conductive member 73 of the comparative example and the thermally conductive member 16 of the present embodiment, and thus is made of graphite.

In subsequent step S02 of FIG. 8, as shown in FIGS. 9A, 9B, the thermally conductive sheet 30 is wound around a core 32 extending in an axial direction Da multiple times. At this time, for example, the thermally conductive sheet 30 is wound around the core 32 while binder 34 is applied to the thermally conductive sheet 30. The thermally conductive sheet 30 wound around the core 32 is bonded in a radial direction Dr of the core 32 by solidification of the applied binder 34.

For example, the core 32 has a columnar shape or a cylindrical shape around a roll axis Cr parallel to the axial direction Da, and is rotatably supported around the roll axis Cr. The core 32 is rotated about the roll axis Cr in order to wind the thermally conductive sheet 30 around the core 32. The binder 34 applied to the thermally conductive sheet 30 becomes the bonding material 18 after the completion of the heat dissipation members 72, 14.

Then, in step S02, the roll member 36 in which the thermally conductive sheet 30 and the binder 34 are laminated in the radial direction Dr is generated by winding and bonding the thermally conductive sheet 30 described above. After the step S02 in FIG. 8, the process proceeds to a step S03.

In step S03, as shown in FIGS. 9B, 9C, the roll member 36 and the core 32 are cut at axial cutting positions A1 in the axial direction Da and divided into pieces. The divided roll member 36 is referred to as a divided roll member 37, and the divided core 32 is referred to as a divided core 38.

In subsequent step S04, as shown in FIGS. 90, 9D, the divided roll member 37 is cut at circumferential cutting positions A2 in the circumferential direction Dc of the core 32 and divided into pieces. FIG. 9D is a diagram illustrating the circumferential cutting positions which are cutting positions when the divided roll member 37 is cut in step S04 in FIG. 8. As a result, the sheet-like heat dissipation member 72 having the thickness direction in the circumferential direction Dc is obtained.

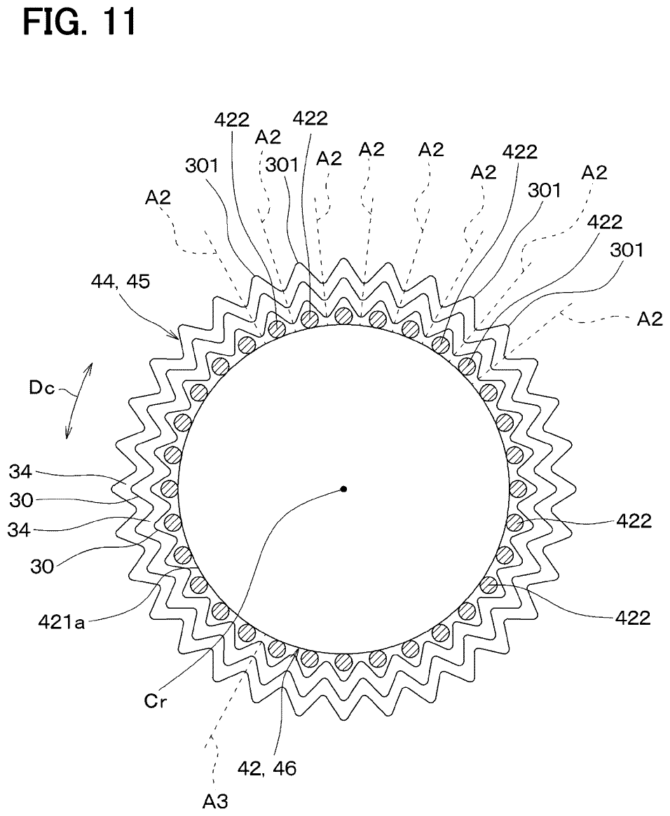

Since the thickness direction of the heat dissipation member 72 is the first direction D1 in FIG. 5, the heat dissipation member 72 is used while being compressed in a direction along the circumferential direction Dc during use. In FIGS. 9C, 9D and FIG. 11 described later, not all of the circumferential cutting positions A2 are displayed, but some of the circumferential cutting positions A2 are displayed.

The method of manufacturing the heat dissipation member 72 of the comparative example is as described above, and the method of manufacturing the heat dissipation member 14 of the present embodiment is also in accordance with the flowchart of FIG. 8 described above. However, as described below, the method of manufacturing the heat dissipation member 14 of the present embodiment has some differences from the method of manufacturing the heat dissipation member 72 of the comparative example described above.

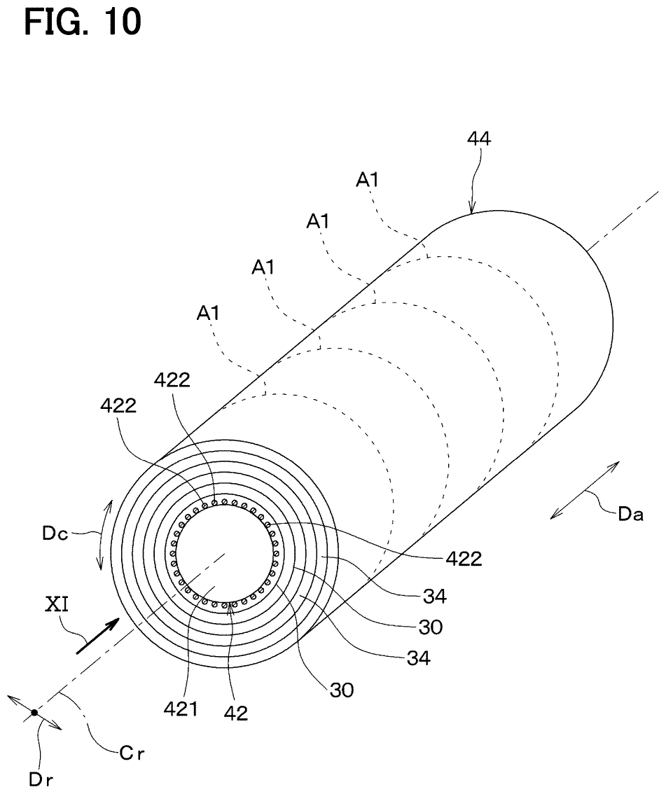

In the manufacturing of the heat dissipation member 14 of the present embodiment, a core 42 around which the thermally conductive sheet 30 is wound in step S02 of FIG. 8 is different from the core 32 of the comparative example. More specifically, as shown in FIG. 10, the core 42 of the present embodiment has a body 421 and protruding portions 422. The body 421 of the present embodiment has the same shape as the core 32 of the comparative example, that is, a columnar shape or a cylindrical shape centered on the roll axis Cr. In short, the core 42 of the present embodiment has a configuration in which the protruding portions 422 are added to the core 32 of the comparative example.

As shown in FIGS. 10, 11, each of the protruding portions 422 is provided so as to protrude outward in the radial direction Dr on an outer peripheral surface 421a of the body 421, which is the outer peripheral surface of the core 42, and extends in the axial direction Da. FIG. 11 is a view showing the circumferential cutting positions which are cutting positions when the divided roll member is cut in step S04 in FIG. 8. The protruding portions 422 are disposed at equal intervals in the circumferential direction Dc. For example, the protruding portions 422 are formed of wires fixed on the outer peripheral surface 421a of the body 421 and extending in the axial direction Da.

In order to avoid confusion between the present embodiment and the comparative example, a member corresponding to the roll member 36 of the comparative example is referred to as a roll member 44 in the present embodiment, and a member corresponding to the divided roll member 37 of the comparative example is referred to as a divided roll member 45 in the present embodiment. Further, a member corresponding to the divided core 38 of the comparative example is referred to as a divided core 46 in the present embodiment. As shown in FIG. 11, similarly to the difference between the core 42 of the present embodiment and the core 32 of the comparative example, the divided core 46 of the present embodiment has a configuration in which protruding portions 422 after division are added to the divided core 38 of the comparative example.

Further, in step S02 of FIG. 8 in the present embodiment, the thermally conductive sheet 30 wound around the core 42 is pressed against the outer peripheral surface 421a of the body 421. As a result, bent portions 301 in which the thermally conductive sheet 30 is bent at arrangement positions of the protruding portions 422 are formed.

Therefore, the roll member 44 of the present embodiment is different from the roll member 36 of the comparative example in that the bent portions 301 are provided, but is the same as the roll member 36 of the comparative example in other points. The divided roll member 45 of the present embodiment is different from the divided roll member 37 of the comparative example in that the divided roll member 45 has the bent portions 301, but is the same as the divided roll member 37 of the comparative example in other points. The bent portion 301 of the thermally conductive sheet 30 of the present embodiment becomes the bent portion 163 of the thermally conductive member 16 in the completed heat dissipation member 14 as illustrated in FIG. 3. In FIG. 11, in order to clearly show a shape of the bent portion 301, the bent shape of the thermally conductive sheet 30 is shown in an extreme manner.

In step S04 of FIG. 8 in the present embodiment, the divided roll member 45 is cut at the circumferential cutting positions A2 in the circumferential direction Dc of the core 42 and divided into pieces. Regarding this, the present embodiment is similar to the comparative example. However, unlike the comparative example, as shown in FIG. 11, the divided roll member 45 is cut at the circumferential cutting positions A2 at which the bent portions 301 of the thermally conductive sheet 30 are interposed in the circumferential direction Dc.

As described above, the method of manufacturing the heat dissipation member 14 of the present embodiment is different from the method of manufacturing the heat dissipation member 72 according to the comparative example. Except for the above, the method of manufacturing the heat dissipation member 14 of the present embodiment is similar to the method of manufacturing the heat dissipation member 72 of the comparative example.

As described above, according to the present embodiment, the heat dissipation member 14 is sandwiched between the first member 11 and the second member 12 arranged in the first direction D1, and is compressed by the first member 11 and the second member 12. The heat dissipation member 14 includes the thermally conductive members 16 each having one end portion 161 connected to the first member 11 in a heat transferable manner and the other end portion 162 connected to the second member 12 in a heat transferable manner. The thermally conductive members 16 are arranged side by side in the second direction D2, conduct heat between the one end portion 161 and the other end portion 162, and have a bent or curved shape in a thermally conductive member transverse section along the first direction D1 and the second direction D2.

Therefore, as shown in FIG. 3, in the present embodiment, as the compressive load Pc compressing the heat dissipation member 14 in the first direction D1 increases, the degree of bending or curving in the curved shape of the thermally conductive member 16 increases as indicated by the arrow Ac. As a result, the thermally conductive member 16 generates a reaction force against the compressive load Pc.

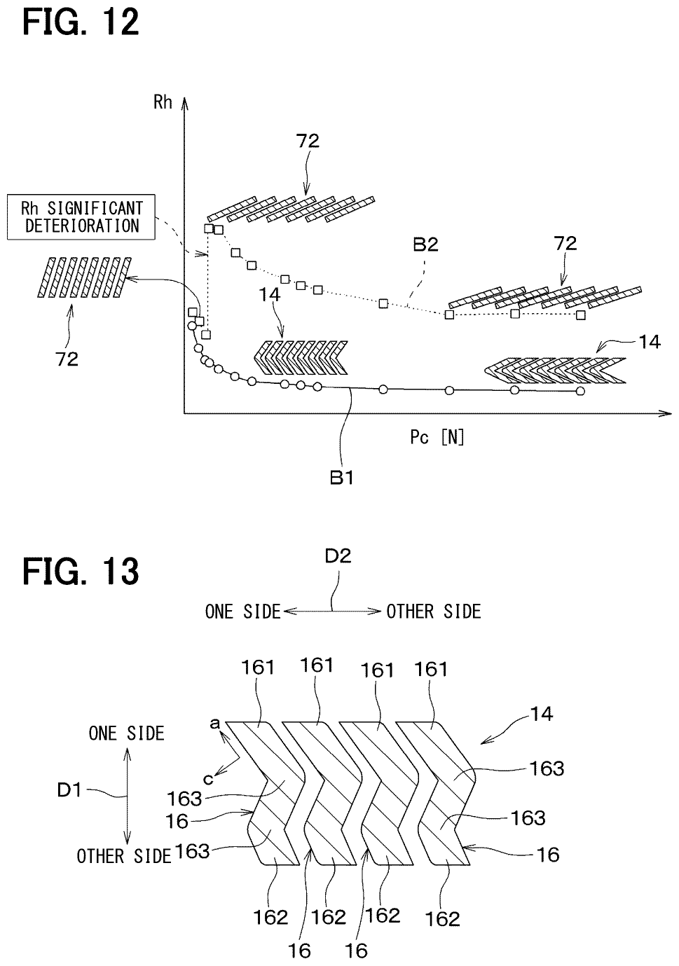

Here, measurement results obtained by measuring compression thermal resistance characteristics B1, B2, which are relationships between module thermal resistance Rh and the compressive load Pc on the heat dissipation members 14, 72, in the present embodiment and the comparative example will be described with reference to FIG. 12. The module thermal resistance Rh is a thermal resistance between a predetermined position of the first member 11 and a predetermined position of the second member 12 across the heat dissipation members 14, 72.

The heat dissipation members 14, 72 illustrated in FIG. 12 schematically represent the shapes of the thermally conductive members 16, 73 that change with a change in the compressive load Pc. In FIG. 12, the compression thermal resistance characteristic B1 of the present embodiment is indicated by a solid line, and the compression thermal resistance characteristic B2 of the comparative example is indicated by a broken line.

As shown in the compression thermal resistance characteristic B2 of the comparative example, in the comparative example, it was confirmed that the module thermal resistance Rh significantly increases when the compressive load Pc on the heat dissipation member 72 is equal to or greater than a certain magnitude. The significant increase in the module thermal resistance Rh, in other words, the significant deterioration in the module thermal resistance Rh is caused by an increase in the inclination angle of the thermally conductive member 73 with respect to the first direction D1 which is the thickness direction of the heat dissipation member 72 as the compressive load Pc increases as shown in FIG. 6.

More specifically, the compressive load Pc acts to incline the thermally conductive member 73 and displace the one end 731 and the other end 732 of the thermally conductive member 73 in the second direction D2 as indicated by an arrow SL in FIG. 6. Accordingly, the contact area between each of the one end 731 and the other end 732 and the contact surfaces 11a, 12a, which are contact partners of the one end 731 and the other end 732, is reduced, which causes significant deterioration of the module thermal resistance Rh. Alternatively, the one end 731 or the other end 732 of some of the thermally conductive members 73 is separated from the contact surfaces 11a, 12a, which are contact partners, due to the inclination of the thermally conductive member 73, which also causes the significant deterioration of the module thermal resistance Rh.

On the other hand, as shown in the compression thermal resistance characteristic B1 of the present embodiment in FIG. 12, in the present embodiment, the significant deterioration of the module thermal resistance Rh in the compression thermal resistance characteristic B2 of the comparative example is avoided. This is because, since the thermally conductive member 16 has the curved shape as shown in FIG. 3, even when the compressive load Pc increases, the action of the one end portion 161 of the thermally conductive member 16 being displaced in the second direction D2 with respect to the other end portion 162 is less likely to occur.

That is, the one end portion 161 of the thermally conductive member 16 is less likely to slip on the contact surface 11a of the first member 11 with which the one end portion 161 is in contact, and the other end portion 162 of the thermally conductive member 16 is less likely to slip on the contact surface 12a of the second member 12 with which the other end portion 162 is in contact. In addition, even when the compressive load Pc increases or decreases, the one end portion 161 and the other end portion 162 are not displaced from each other, and a contact area in which the one end portion 161 is in contact with the contact surface 11a of the first member 11 and a contact area in which the other end portion 162 is in contact with the contact surface 12a of the second member 12 are easily maintained.

As described above, in the present embodiment, for example, compared to the comparative example, even when the compressive load Pc on the heat dissipation member 14 increases, the contact area between the one end portion 161 of the thermally conductive member 16 and the first member 11 and the contact area between the other end portion 162 of the thermally conductive member 16 and the second member 12 are less likely to decrease. Therefore, a phenomenon in which the module thermal resistance Rh increases as the compressive load Pc increases can be avoided.

In addition, according to the present embodiment, the core 42 around which the thermally conductive sheet 30 is wound in step S02 of FIG. 8 includes the protruding portions 422 that is provided to protrude outward in the radial direction Dr on the outer peripheral surface 421a of the body 421 and extends in the axial direction Da. Then, in step S02, the thermally conductive sheet 30 wound around the core 42 is pressed against the outer peripheral surface 421a of the body 421, and thus the bent portion 301 in which the thermally conductive sheet 30 is bent at the arrangement position of the protruding portions 422 is formed.

Further, in step S03, the divided roll member 45 in which the roll member 44 including the bent portion 301 is divided in the axial direction Da is obtained, and in subsequent step S04, the divided roll member 45 is cut at the circumferential cutting positions A2 in the circumferential direction Dc of the core 42 and divided into the pieces. At this time, the divided roll member 45 is cut such that the circumferential cutting positions A2 sandwich the bent portion 301 of the thermally conductive sheet 30 in the circumferential direction Dc. Through this step S04, the heat dissipation member 14 is obtained.

Therefore, the heat dissipation member 14 of the present embodiment can be easily produced. At this time, the thermally conductive sheet 30 after being cut in step S04 becomes the thermally conductive members 16 included in the heat dissipation member 14. Then, the bent portion 301 is formed when the roll member 44 is generated in step S02, whereby the bent shape of the thermally conductive member 16 is formed. That is, the bent portion 301 of the thermally conductive sheet 30 becomes the bent portion 163 of the thermally conductive member 16 in the completed heat dissipation member 14, and is included in the bent shape of the thermally conductive member 16.

According to the present embodiment, as shown in FIG. 3, the curved shape of the thermally conductive member 16 is bent to be convex to one end of the second direction D2 at a position away from the one end portion 161 and the other end portion 162 within a range between the one end portion 161 and the other end portion 162 in the first direction D1. Therefore, for example, compared to a case where the curved shape of the thermally conductive member 16 is gently curved without being bent, the curved shape in the thermally conductive member 16 can be clearly formed.

According to the present embodiment, the thermally conductive member 16 contains graphite. Therefore, the high thermal conductivity in heat conduction in the first direction D1 which is the thickness direction of the heat dissipation member 14 can be obtained. For example, the higher thermal conductivity in heat conduction between the first member 11 and the second member 12 can be obtained than in a case where the first member 11 and the second member 12 are joined by solder and heat is conducted between the first member 11 and the second member 12 via the solder.

### Second Embodiment

A second embodiment of the present disclosure is described next. The present embodiment is explained mainly with respect to points different from those of the first embodiment. In addition, explanations of the same or equivalent portions as those in the above embodiment is omitted or simplified. The same applies to a description of the embodiments described later.

As shown in FIG. 13, also in the present embodiment, similarly to the first embodiment, each of thermally conductive members 16 included in a heat dissipation member 14 has the above-described bent shape. However, in a cross section of the thermally conductive member shown in FIG. 13, the bent shape of the thermally conductive member 16 of the present embodiment is a zigzag shape including bent portions 163.

More specifically, the thermally conductive member 16 of the present embodiment includes two bent portions 163 arranged in the first direction D1. One of the two bent portions 163 is disposed in one direction in the first direction D1, and has a shape bent to be convex in the other direction in the second direction D2. The other of the two bent portions 163 is disposed in the other direction in the first direction D1, and has a shape bent to be convex in one direction in the second direction D2. The shape of the thermally conductive member 16 shown in FIG. 13 is a shape in a no-load state in which the heat dissipation member 14 is not compressed.

The present embodiment is similar to the first embodiment, except for the above described aspects. Thus, the present embodiment can achieve the advantages obtained by the configuration common to the first embodiment described above in a similar manner as in the first embodiment.

### Third Embodiment

A third embodiment of the present disclosure is described next. The present embodiment is explained mainly with respect to points different from those of the first embodiment.

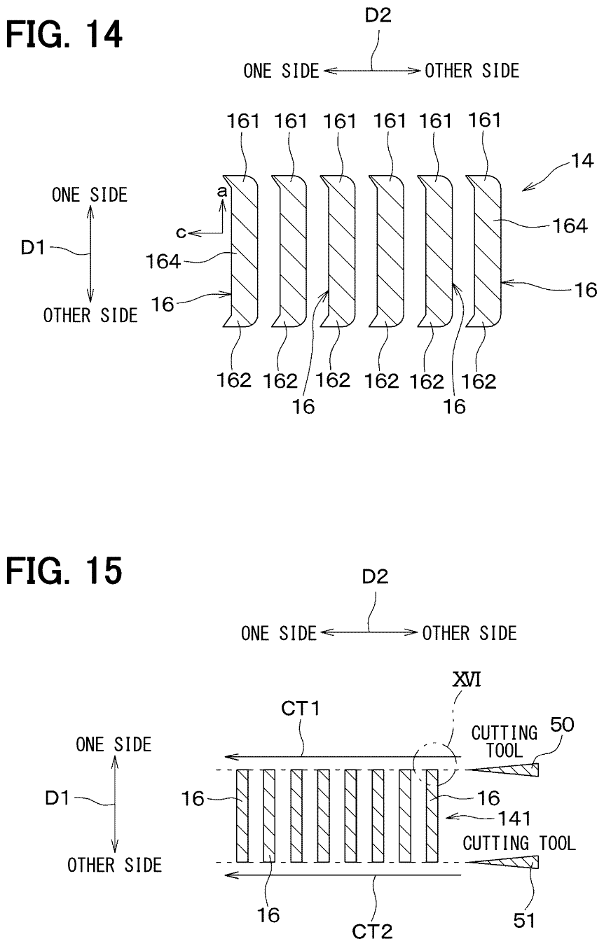

As shown in FIG. 14, also in the present embodiment, similarly to the first embodiment, each of thermally conductive members 16 included in a heat dissipation member 14 has the above-described bent shape. However, in a cross section of the thermally conductive member shown in FIG. 14, a bent shape of the thermally conductive member 16 of the present embodiment does not include the bent portion 163. The shape of the thermally conductive member 16 shown in FIG. 14 is a shape in a no-load state in which the heat dissipation member 14 is not compressed.

More specifically, the thermally conductive member 16 of the present embodiment has a body portion 164 which is a portion between one end portion 161 and the other end portion 162 of the thermally conductive member 16, and the body portion 164 is formed so as to linearly extend in the first direction D1. Each of the one end portion 161 and the other end portion 162 of the thermally conductive member 16 is deformed so as to be shifted to one end in the second direction D2 with respect to the body portion 164.

As a result, in the first cross section of FIG. 14, the thermally conductive member 16 has a curved shape in which one end in the second direction D2 is concave and the other end in the second direction D2 is convex as a whole from the one end portion 161 to the other end portion 162. That is, each of the thermally conductive members 16 has the above-described bent shape.

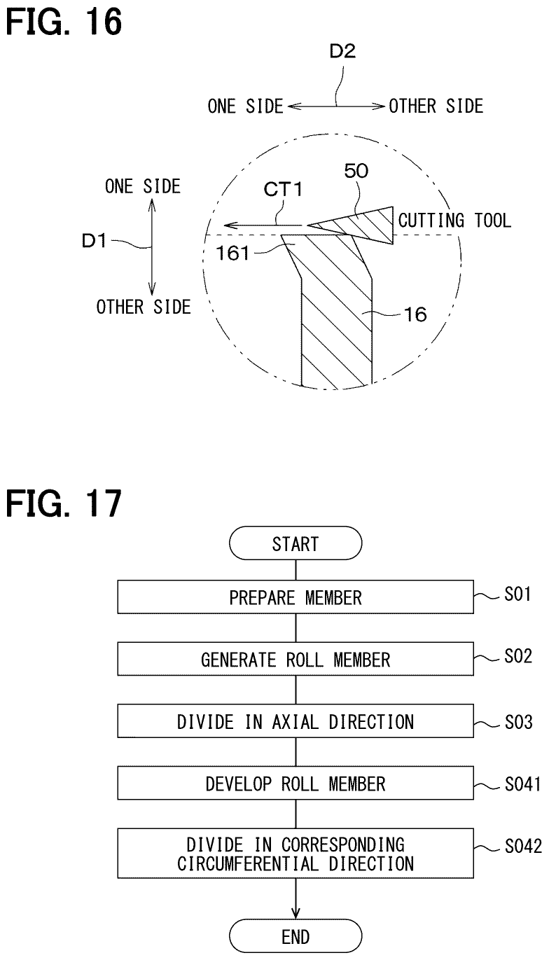

The curved shape of the thermally conductive member 16 of the present embodiment can be formed by the manufacturing method shown in FIGS. 15, 16. That is, prior to cutting operation of cutting out the heat dissipation member 14 by a cutting tools 50, 51, a material 141 of the heat dissipation member 14 is first prepared. In the material 141 of the heat dissipation member 14, the thermally conductive members 16 have a shape linearly extending along the first direction D1.

In the cutting operation of the heat dissipation member 14, as indicated by an arrow CT1 in FIGS. 15, 16, the material 141 of the heat dissipation member 14 is cut from the other end to the one end in the second direction D2 by the cutting tool 50, thereby forming the one end portion 161 of the thermally conductive member 16. At this time, as shown in FIG. 16, since the one end portion 161 of the thermally conductive member 16 is formed while being pressed from the other end to the one end in the second direction D2 by the cutting tool 50, as described above, the one end portion 161 has a shape deformed so as to be shifted to the one end in the second direction D2 with respect to the body portion 164.

Similarly, in the cutting operation of the heat dissipation member 14, as indicated by an arrow CT2 in FIG. 15, the material 141 of the heat dissipation member 14 is cut by the cutting tool 51 from the other end to the one end in the second direction D2, thereby forming the other end portion 162 of the thermally conductive member 16. At this time, similarly to the one end portion 161 of the thermally conductive member 16, the other end portion 162 of the thermally conductive member 16 is formed while being pressed from the other end to the one end in the second direction D2 by the cutting tool 51. Therefore, as described above, the other end portion 162 of the thermally conductive member 16 has a shape deformed to be shifted to the one end in the second direction D2 with respect to the body portion 164.

As described above, the curved shape of the thermally conductive member 16 of the present embodiment can be formed.

The present embodiment is similar to the first embodiment, except for the above described aspects. Thus, the present embodiment can achieve the advantages obtained by the configuration common to the first embodiment described above in a similar manner as in the first embodiment.

### Fourth Embodiment

A fourth embodiment of the present disclosure is described next. The present embodiment is explained mainly with respect to points different from those of the first embodiment.

All thermally conductive members 16 included in a heat dissipation member 14 of the present embodiment are made of aluminum or an aluminum alloy instead of graphite. In short, all the thermally conductive members 16 of the present embodiment contain aluminum.

Even in this case, similarly to the first embodiment, a high thermal conductivity in the thermal conduction between the first member 11 and the second member 12 can be obtained.

The present embodiment is similar to the first embodiment, except for the above described aspects. Thus, the present embodiment can achieve the advantages obtained by the configuration common to the first embodiment described above in a similar manner as in the first embodiment.

Note that the present embodiment is a modification based on the first embodiment, but it is possible to combine this embodiment with the second embodiment or the third embodiment described above.

### Fifth Embodiment

A fifth embodiment of the present disclosure is described next. The present embodiment is explained mainly with respect to points different from those of the first embodiment.

All thermally conductive members 16 included in the heat dissipation member 14 of the present embodiment are made of silver or a silver alloy instead of graphite. In short, all the thermally conductive members 16 of the present embodiment contain silver.

Even in this case, similarly to the first embodiment, a high thermal conductivity in the thermal conduction between the first member 11 and the second member 12 can be obtained.

The present embodiment is similar to the first embodiment, except for the above described aspects. Thus, the present embodiment can achieve the advantages obtained by the configuration common to the first embodiment described above in a similar manner as in the first embodiment.

Note that the present embodiment is a modification based on the first embodiment, but it is possible to combine this embodiment with the second embodiment or the third embodiment described above.

### Sixth Embodiment

A sixth embodiment of the present disclosure is described next. The present embodiment is explained mainly with respect to points different from those of the first embodiment.

In manufacturing of a heat dissipation member 14 of the present embodiment, the heat dissipation member 14 is manufactured according to a flowchart of FIG. 17 instead of FIG. 8. Although steps S01, S02, and S03 in FIG. 17 are the same as steps S01, S02, and S03 in FIG. 8, step S04 in FIG. 8 is replaced with steps S041 and S042 in FIG. 17.

More specifically, in the flowchart of FIG. 17, the process proceeds to step S041 after step S03. In step S041, a divided roll member 45 is cut at a predetermined position A3 (see FIG. 11) in a circumferential direction Dc. The predetermined position A3 may be any one position in the circumferential direction Dc. By the cutting at the predetermined position A3, the divided roll member 45 can be removed from a divided core 46.

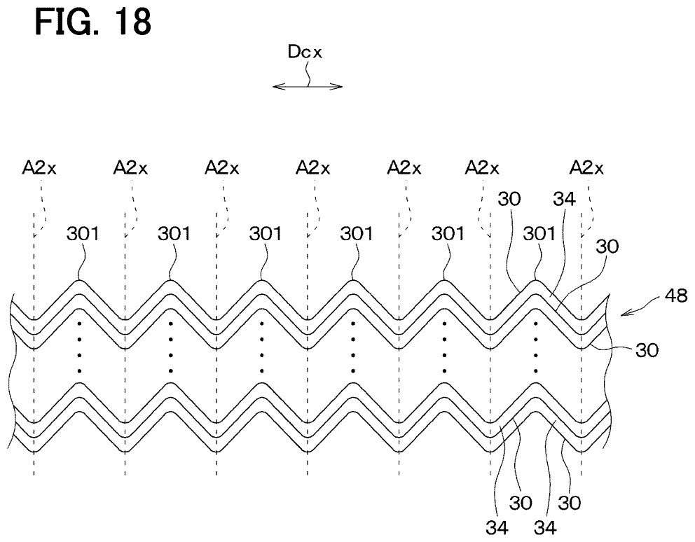

After cutting at the predetermined position A3, the divided roll member 45 is removed from the divided core 46, and is developed into, for example, a flat plate shape. FIG. 18 shows a part of the developed member 48 obtained by developing the divided roll member 45. In the developed member 48 developed in this manner, a bent shape of a bent portion 301 is also maintained.

As shown in FIG. 18, bent portions 301 of the developed member 48 are arranged in a corresponding circumferential direction Dcx corresponding to the circumferential direction Dc of FIG. 11 in the developed member 48. That is, an arrangement direction of the bent portions 301 in the divided roll member 45 of FIG. 11 is the circumferential direction Dc, and the arrangement direction of the bent portions 301 in the developed member 48 of FIG. 18 is the corresponding circumferential direction Dcx. After the step S041 in FIG. 17, the process proceeds to a step S042.

In step S042 of FIG. 17, the developed member 48 is cut at the corresponding circumferential cutting positions A2x in the corresponding circumferential direction Dcx and divided into pieces. The corresponding circumferential cutting position A2x is a position corresponding to the circumferential cutting position A2 of the first embodiment. Therefore, as shown in FIG. 18, the developed member 48 is cut such that the corresponding circumferential cutting positions A2x sandwich the bent portion 301 of the thermally conductive sheet 30 in the corresponding circumferential direction Dcx.

As described above, even when the heat dissipation member 14 is manufactured according to the flowchart of FIG. 17, the same heat dissipation member 14 as that of the first embodiment can be easily produced.

The present embodiment is similar to the first embodiment, except for the above described aspects. Thus, the present embodiment can achieve the advantages obtained by the configuration common to the first embodiment described above in a similar manner as in the first embodiment.

Note that the present embodiment is a modification based on the first embodiment, but it is possible to combine the present embodiment with any of the second, fourth, and fifth embodiments described above.

### Other Embodiments

In the first embodiment described above, as shown in FIG. 3, the curved shape of the thermally conductive member 16 is a shape bent so as to be convex toward one end in the second direction D2 at an intermediate position away from each of the one end portion 161 and the other end portion 162 of the thermally conductive member 16 in the first direction D1. However, this is an example. For example, conversely, the curved shape of the thermally conductive member 16 may be a shape bent so as to be convex toward the other end in the second direction D2 at the intermediate position of the thermally conductive member 16.

In the first embodiment described above, the curved shape of the thermally conductive member 16 shown in FIG. 3 is a shape that is locally bent at the bent portion 163, but this is merely an example. For example, the curved shape of the thermally conductive member 16 may be a shape smoothly curved between the one end portion 161 and the other end portion 162.

In the first and sixth embodiments described above, as shown in FIGS. 8, 17, the roll member 44 is cut so as to be divided in the axial direction Da in step S03, but it is also assumed that the process of step S03 is not performed.

In the first embodiment described above, as shown in FIG. 8, the roll member 44 is cut so as to be divided in the axial direction Da and then divided in the circumferential direction Dc. However, for example, conversely, the roll member 44 may be cut so as to be divided in the circumferential direction Dc and then divided in the axial direction Da. Various procedures for cutting the roll member 44 are assumed.

In the sixth embodiment described above, as shown in FIG. 17, after the roll member 44 is divided in the axial direction Da, the divided roll member 45 after the division is removed from the divided core 46 and developed into, for example, a flat plate shape, but this is an example. For example, conversely, the roll member 44 may be cut at the predetermined position A3 (see FIG. 11), removed from the core 42, and developed into a flat plate shape, and then the developed member 48 obtained by developing the roll member 44 may be divided in the corresponding axial direction corresponding to the axial direction Da in the developed member 48.

In the first embodiment described above, as shown in FIG. 11, for example, the protruding portions 422 are formed of wires fixed on the outer peripheral surface 421a of the body 421 and extending in the axial direction Da, but this is an example. For example, the protruding portions 422 may be integrated with the body 421 and may be configured as portions protruding outward in the radial direction Dr from the body 421.

The present disclosure is not limited to the specific embodiments described above, and various modifications can be made. In addition, the embodiments described above are not unrelated to each other, and can be appropriately combined unless the combination is obviously impossible.

Individual elements or features of a particular embodiment are not necessarily essential unless it is specifically stated that the elements or the features are essential in the foregoing description, or unless the elements or the features are obviously essential in principle. A quantity, a value, an amount, a range, or the like, if specified in the above-described example embodiments, is not necessarily limited to the specific value, amount, range, or the like unless it is specifically stated that the value, amount, range, or the like is necessarily the specific value, amount, range, or the like, or unless the value, amount, range, or the like is obviously necessary to be the specific value, amount, range, or the like in principle. Further, in each of the embodiments described above, when referring to the material, shape, positional relationship, and the like of the components and the like, except in the case where the components are specifically specified, and in the case where the components are fundamentally limited to a specific material, shape, positional relationship, and the like, the components are not limited to the material, shape, positional relationship, and the like.

While the present disclosure has been described with reference to embodiments thereof, it is to be understood that the disclosure is not limited to the embodiments and constructions. To the contrary, the present disclosure is intended to cover various modification and equivalent arrangements. In addition, while the various elements are shown in various combinations and configurations, which are exemplary, other combinations and configurations, including more, less or only a single element, are also within the spirit and scope of the present disclosure.

What is claimed is:

1. A heat dissipation member provided between a first member and a second member in a first direction and compressed by the first member and the second member to conduct heat between the first member and the second member, the heat dissipation member comprising:
thermally conductive members each having one end portion provided at one end in the first direction and thermally connected to the first member and an other end portion provided at an other end in the first direction and thermally connected to the second member, the heat conductive members being arranged side by side in a second direction perpendicular to the first direction and conducting heat between the one end portion and the other end portion, wherein
each of the thermally conductive members has a curved shape which is bent or curved in a cross section taken along the first direction and the second direction.

2. The heat dissipation member according to claim 1, wherein
the curved shape is a shape that is bent to be convex to one side or an other side in the second direction at an intermediate position away from the one end portion and the other end portion within a range between the one end portion and the other end portion in the first direction.

3. The heat dissipation member according to claim 1, wherein
the thermally conductive members include graphite.

4. The heat dissipation member according to claim 1, wherein
the thermally conductive members include aluminum.

5. The heat dissipation member according to claim 1, wherein
the thermally conductive members include silver.

6. A semiconductor device comprising:
a first member including a semiconductor element and generating heat;
a second member arranged in a first direction with respect to the first member;
a heat dissipation member provided between the first member and the second member and compressed by the first member and the second member, wherein
the heat dissipation member has thermally conductive members each having one end portion provided on one side which faces the first member in the first direction and thermally connected to the first member and an other end portion which faces away from the first member in the first direction and thermally connected to the second member,
the thermally conductive members are arranged side by side in a second direction perpendicular to the first direction and conduct heat between the one end portion and the other end portion, and
each of the thermally conductive members has a curved shape which is bent or curved in a cross section taken along the first direction and the second direction.

7. A method of manufacturing a heat radiating member provided between a first member and a second member and compressed by the first member and the second member to conduct heat between the first member and the second member, the method comprising:
producing a roll member including a thermally conductive sheet, which has a sheet shape, stacked in a radial direction of a core, which extends in an axial direction, by winding the thermally conductive sheet having thermal conductivity multiple times around the core and joining the thermally conductive sheet in the radial direction; and
obtaining a heat dissipation member by cutting the roll member at cutting positions so as to divide the roll member in a circumferential direction of the core, wherein
the core has a projecting portion provided on an outer surface of the core so as to project outward in the radial direction and to extend in the axial direction,
the producing includes forming a bent portion where the thermally conductive sheet is bent at a position where the protruding portion is provided by pressing the thermally conductive sheet against the outer surface of the core, and
the obtaining includes cutting the roll member at the cutting positions between which the bent portion of the thermally conductive sheet is interposed in the circumferential direction.

8. A method of manufacturing a heat radiating member provided between a first member and a second member and compressed by the first member and the second member to conduct heat between the first member and the second member, the method comprising:
producing a roll member including a thermally conductive sheet, which has a sheet shape, stacked in a radial direction of a core, which extends in an axial direction, by winding the thermally conductive sheet having thermal conductivity multiple times around the core and joining the thermally conductive sheet in the radial direction;
cutting the roll member at a predetermined position in a circumferential direction of the core;
removing the roll member from the core;
expanding the roll member; and
obtaining a heat dissipation member by cutting the expanded member at cutting positions so as to divide the expanded member in a corresponding circumferential direction corresponding to the circumferential direction of the expanded member, wherein
the core has a projecting portion provided on an outer surface of the core so as to project outward in the radial direction and to extend in the axial direction,
the producing includes forming a bent portion where the thermally conductive sheet is bent at a position where the protruding portion is provided by pressing the thermally conductive sheet against the outer surface of the core, and
the obtaining includes cutting the expanded member at the cutting positions between which the bent portion of the thermally conductive sheet is interposed in the corresponding circumferential direction.
